(19) United States
(12) Patent Application Publication
(10) Pub. No.: US 2025/0173492 A1
(43) Pub. Date: May 29, 2025

(54) Reducing Unknown Values in Automatic Test Pattern Generation Testing

(71) Applicant: Google LLC, Mountain View, CA (US)

(72) Inventors: Veerabhadra Rao Vasa, Bengaluru (IN); Vevekanenda Gonugunta, Chirala (IN)

(73) Assignee: Google LLC, Mountain View, CA (US)

(21) Appl. No.: 19/039,346

(22) Filed: Jan. 28, 2025

Related U.S. Application Data
(60) Provisional application No. 63/750,115, filed on Jan. 27, 2025.

(51) Int. Cl. G06F 30/333

(52) U.S. Cl. CPC G06F 30/333

(57) ABSTRACT

Systems and techniques directed at reducing unknown values in automatic test pattern generation testing are disclosed. Various paths through a circuit design that generate an unknown value (e.g., not a value of zero or a value of one) during automatic test pattern generation testing are identified. A value override circuit may be inserted into paths identified as providing an unknown value. The value override circuit may be programmed to provide an output of a value of zero or a value of one during automatic test pattern generation testing. The insertion of value override circuits within a circuit design may reduce unknown values in automatic test pattern generation testing of the circuit design. The reduction of unknown values generated during automatic test pattern generation testing of a circuit design saves time and, thus, money.

### CROSS-REFERENCE TO RELATED APPLICATION(S)

This application claims the benefit of U.S. Provisional Patent Application Ser. No. 63/750,115 filed on Jan. 27, 2025, the disclosure of which is incorporated by reference herein in its entirety.

### SUMMARY

This document describes systems and techniques directed at reducing unknown values in automatic test pattern generation testing.

In one implementation, the techniques described herein relate to a method for reducing unknown values in automatic test pattern generation testing. The method includes adding, at a boundary of a circuit design, input mode controls. The method includes inserting standard core wrapper cells into the circuit design. The method includes identifying paths of the circuit design that contribute to unknown values during testing of the circuit design. The method includes inserting a plurality of value override circuits into one or more of the identified paths. The input mode controls are configured to individually control the plurality of value override circuits.

The method includes performing scan insertion using the plurality of value override circuits to initialize test values. The method includes performing automatic test pattern generation testing, the plurality of value override circuits configured, by the initialized test values, to reduce a number of unknown values in results from test logic of the circuit design. In one aspect, the value override circuits are dedicated wrapper cells. In another aspect, the value override circuits each include an OR gate coupled with an AND gate and a control transmit data register coupled with the OR gate and the AND gate. The control transmit data register may be configured to provide a value of zero, a value of one, or an unknown value to a first input of the OR gate and to provide a value of zero or a value of one to a first input of the AND gate.

The details of one or more implementations are set forth in the accompanying Drawings and the following Detailed Description. Other features and advantages will be apparent from the Detailed Description, the Drawings, and the Claims. This Summary is provided to introduce subject matter that is further described in the Detailed Description. Accordingly, a reader should not consider the Summary to describe essential features or limit the scope of the claimed subject matter.

### BRIEF DESCRIPTION OF DRAWINGS

Systems and techniques for reducing unknown values in automatic test pattern generation testing are described with reference to the following drawings. The same numbers are used throughout the drawings to reference like features and components.

FIG. 1 illustrates a schematic of a portion of an example circuit design that utilizes dedicated wrapper cells as value override circuits that implement aspects of reducing unknown values in automatic test pattern generation testing.

FIG. 2 illustrates a schematic of a portion of an example circuit design that utilizes dedicated wrapper cells as value override circuits with control registers coupled with the dedicated wrapper cells that implement aspects of reducing unknown values in automatic test pattern generation testing.

FIG. 3 illustrates a schematic of a portion of an example circuit design that utilizes value override circuits that implement aspects of reducing unknown values in automatic test pattern generation testing.

FIG. 4 illustrates a schematic of an example value override circuit that implements aspects of reducing unknown values in automatic test pattern generation testing.

FIG. 5 is a flow chart of an example method that reduces unknown values in automatic test pattern generation testing.

### DETAILED DESCRIPTION

### Overview

The presence of unknown values (e.g., any value other than the value of zero or the value of one) in a digital circuit design causes challenges during automatic test pattern generation testing of the digital circuit. For example, unknown values increase the testing run time and increase the pattern count of the automatic test pattern generation testing. These potential testing disadvantages increase the cost of the circuit design. Additionally, the presence of unknown values may create false paths, create fault aliasing, and provide unpredictable logic behavior.

There may be various sources of unknown values (e.g., sources of X or X sources) for a digital circuit design during automatic test pattern generation testing. For example, a false path or a multi-cycle path may cause an unknown value. A multi-cycle path of the circuit design is a path that during automatic test pattern generation testing takes longer than one clock cycle to complete the scan and capture. Uninitialized logic and unmodelled logic within the circuit design may also provide unknown values during automatic test pattern generation testing. Likewise, analog modules within the circuit design may also provide unknown values during the automatic test pattern generation testing.

There are various locations within the circuit design that may provide unknown values. For example, an unknown value may be across clock domains or at interfaces between an element at a hierarchical level. Unknown values may also be generated when a path of the circuit design is tested at a lower frequency during the automatic test pattern generation testing than the actual clock speed. A synopsys design constraints (SDC) file format may be used to provide exceptions (e.g., sources of unknown values) to the automatic test pattern generation tools. An automatic test pattern generation simulation may use the SDC file format to identify and mask the exceptions at the capture side. However, masking the exceptions does not change the unknown values to an acceptable value (e.g., a value of zero, a value of one).

To this end, this document describes systems and techniques directed at reducing unknown values or X sources in automatic test pattern generation testing.

Upon identification of paths that generate an unknown value (e.g., not a value of zero or a value of one), a value override circuit (e.g., dedicated wrapper cell, custom logic circuit) may be inserted into an identified path. The value override circuit may be programmed to provide an output of a value of zero or a value of one during automatic test pattern generation testing. The insertion of value override circuits within a circuit design may reduce unknown values in automatic test pattern generation testing of the circuit design. Further, the insertion of value override circuits may also reduce automatic test pattern generation runtime and also reduce the total pattern count of the testing. Depending on the circuit design, the reduction of unknown values and reduction of automatic test pattern generation runtime results may vary. In at least one test case, the insertion of value override circuits into a circuit design reduced the number of unknown values by approximately ninety-nine (99) percent and reduced the runtime by approximately thirty (30) percent.

In one aspect, the value override circuit may be a dedicated wrapper cell. The dedicated wrapper cell, inserted in a path identified as providing an unknown value, may be configured by control registers to provide a value of zero or a value of one. The dedicated wrapper cell may also be configured by control registers to enable a functional exception to pass through the path. In this event, the dedicated wrapper cell is programmed to be “transparent,” enabling the functional exception to pass through the dedicated wrapper cell. In other words, the dedicated wrapper cell does not provide an output value of either a zero or a one when in this mode.

In another aspect, the value override circuit may be a circuit including logic that is inserted in a path identified as providing an unknown value. The circuit includes an OR gate coupled with an AND gate and a control transmit data register coupled with the OR gate and the AND gate. The control transmit data register may be coupled with a first input of the OR gate and a first input of the AND gate. A second input of the OR gate and an output of the AND gate may be coupled with the identified path. A second input of the AND gate may be coupled with an output of the OR gate. The control transmit data register may be configured to provide a value of zero, a value of one, or an unknown value to the first input of the OR gate and to provide a value of zero or a value of one to the first input of the AND gate. The control transmit data register may program the value override circuit to output a value of 0 or a value of 1. Further, the control transmit data register may program the value override circuit to enable a functional exception to pass through the path.

The following discussion describes techniques that may be employed in the example operating apparatuses and environments. Although systems and techniques for reducing unknown values in automatic test pattern generation testing are described, it is to be understood that the subject of the appended Claims is not necessarily limited to the specific features or methods described. Rather, the specific features are disclosed as example implementations and reference is made to the operating environment by way of example only.

### Example Systems and Operational Schemes

Systems and techniques directed at reducing unknown values in automatic test pattern generation (ATPG) testing are disclosed. Various paths through a circuit design that generate an unknown value (e.g., not a value of zero or a value of one) during automatic test pattern generation testing are identified. A value override circuit may be inserted into paths identified as providing an unknown value. The value override circuit may be configured (e.g., programmed) to provide an output of a value or zero or a value of one during automatic test pattern generation testing. The insertion of value override circuits within a circuit design may reduce the unknown values in automatic test pattern generation testing of the circuit design. The reduction of unknown values generated during automatic test pattern generation testing of a circuit design saves time and, thus, money. The value override circuit may be a dedicated wrapper cell configured by registers or may be a circuit containing logic elements that may be controlled by a group control block coupled with each custom circuit and configured to individually control each coupled value override circuit.

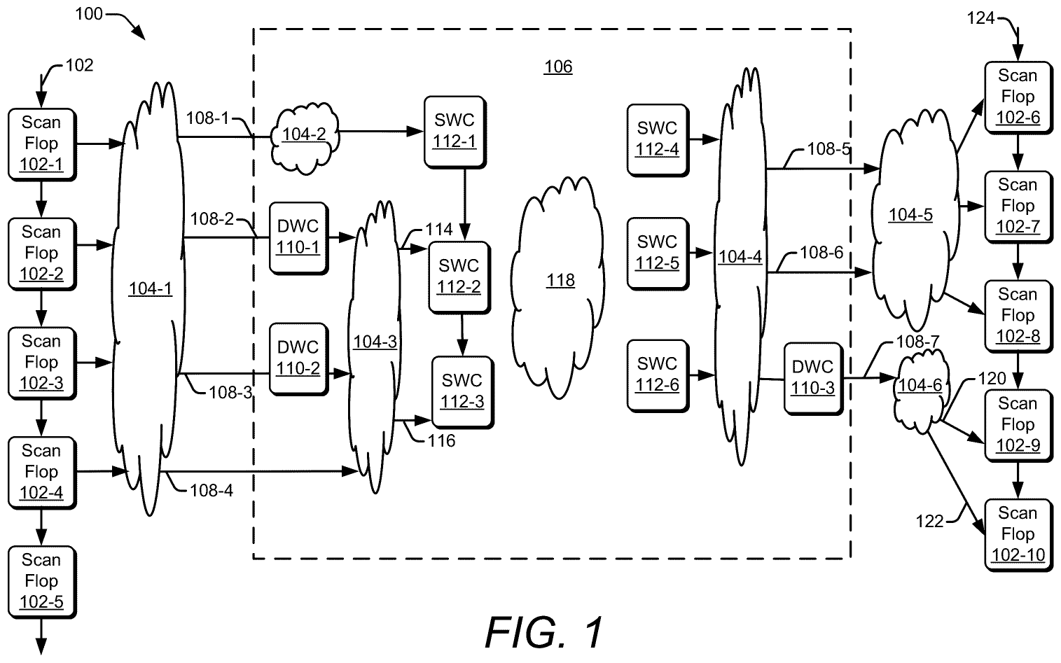

FIG. 1 illustrates a schematic of a portion 106 of an example circuit design 100 that utilizes dedicated wrapper cells 110-1, 110-2, 110-3 as value override circuits that implement aspects of reducing unknown values in automatic test pattern generation testing. For example, a first dedicated wrapper cell 110-1 may be a first value override circuit, a second dedicated wrapper cell 110-2 may be a second value override circuit, and a third dedicated wrapper cell 110-3 may be a third value override circuit. The portion 106 of the circuit design 100 may be various automatic test pattern generation partitions as would be appreciated by one of ordinary skill in the art having the benefit of this disclosure. The circuit design 100 includes a scan chain 102 that includes scan flops 102-1, 102-2, 102-3, 102-4, 102-5. The number of scan flops 102-1, 102-2, 102-3, 102-4, 102-5 of the scan chain 102 is shown for illustrative purposes and may be varied as would be appreciated by one of ordinary skill in the art having the benefit of this disclosure. The scan chain 102 is coupled with a first logic 104-1 of the circuit design 100. The scan chain 102 is utilized to perform a scan during automatic test pattern generation testing as would be appreciated by one of ordinary skill in the art having the benefit of this disclosure. A first pin 108-1 of the circuit design 100 is coupled between the first logic 104-1, a second logic 104-2, and a first shared wrapper cell 112-1. Shared wrapper cells (SWC) 112-1, 112-2, 112-3, 112-4, 112-5, 112-6 are standard core wrapper cells that are inserted into the circuit design 100 to perform automatic test pattern generation testing of a circuit design, and the number and/or location may be varied as would be appreciated by one of ordinary skill in the art having the benefit of this disclosure.

A second pin 108-2, a third pin 108-3, and a fourth pin 108-4 of the circuit design 100 are coupled between the first logic 104-1 and a third logic 104-3. The first logic 104-1, the second logic 104-2, and the third logic 104-3 may include various combinations of logic and/or circuit design elements as would be appreciated by one of ordinary skill in the art having the benefit of this disclosure. The portion 106 of the circuit design 100 may include core logic 118 as may be appreciated by one of ordinary skill in the art having the benefit of this disclosure.

Without the insertion of value override circuits (e.g., a first dedicated wrapper cell 110-1, a second dedicated wrapper cell 110-2), the third logic 104-3 provides unknown values to a second shared wrapper cell 112-2 and a third shared wrapper cell 112-3. To mitigate these unknown values, the first dedicated wrapper cell 110-1 has been inserted on a path through the second pin 108-2 and the second dedicated wrapper cell 110-2 has been inserted on a path through the third pin 108-3. The first dedicated wrapper cell 110-1 and the second dedicated wrapper cell 110-2 may be configured to provide that the third logic 104-3 generates known values 114, 116 (e.g., a value of zero, a value of one) to the second shared wrapper cell 112-2 and the third shared wrapper cell 112-3, respectively, during automatic test pattern generation testing. The first dedicated wrapper cell 110-1 and the second dedicated wrapper cell 110-2 may also be configured to enable a functional exception to pass through the paths without modifying the values as discussed herein.

The portion 106 of the circuit design 100 may also include a fourth shared wrapper cell 112-4, a fifth shared wrapper cell 112-5, and a sixth shared wrapper cell 112-6 coupled with a fourth logic 104-4. The fourth shared wrapper cell 112-4, the fifth shared wrapper cell 112-5, and the sixth shared wrapper cell 112-6 may be standard core wrapper cells inserted into the circuit design 100 to perform automatic test pattern generation testing of the circuit design 100 as discussed herein. The fourth shared wrapper cell 112-4, the fifth shared wrapper cell 112-5, and the sixth shared wrapper cell 112-6 are coupled to a capture chain 124 used to capture the values resulting in the scan of the automatic test pattern generation testing. The capture chain 124 may include scan flops 102-6, 102-7, 102-8, 102-9, 102-10. The number of scan flops 102-6, 102-7, 102-8, 102-9, 102-10 of the capture chain 124 is shown for illustrative purposes and may be varied as would be appreciated by one of ordinary skill in the art having the benefit of this disclosure.

The fourth shared wrapper cell 112-4, the fifth shared wrapper cell 112-5, and the sixth shared wrapper cell 112-6 are coupled to a capture chain 124 by a fourth logic 104-4, a fifth pin 108-5, a sixth pin 108-6, a seventh pin 108-7, a fifth logic 104-5, and a sixth logic 104-6. The number and/or configuration of scan flops (e.g., scan flops 102-1-102-10), shared wrapper cells (e.g., shared wrapper cells 112-1-112-6), logic (e.g., logic 104-1-104-6, core 118), and dedicated wrapper cells (e.g., dedicated wrapper cells 110-1-110-3) are shown for illustrative purposes and may be varied depending on the circuit design 100 as would be appreciated by one of ordinary skill in the art having the benefit of this disclosure.

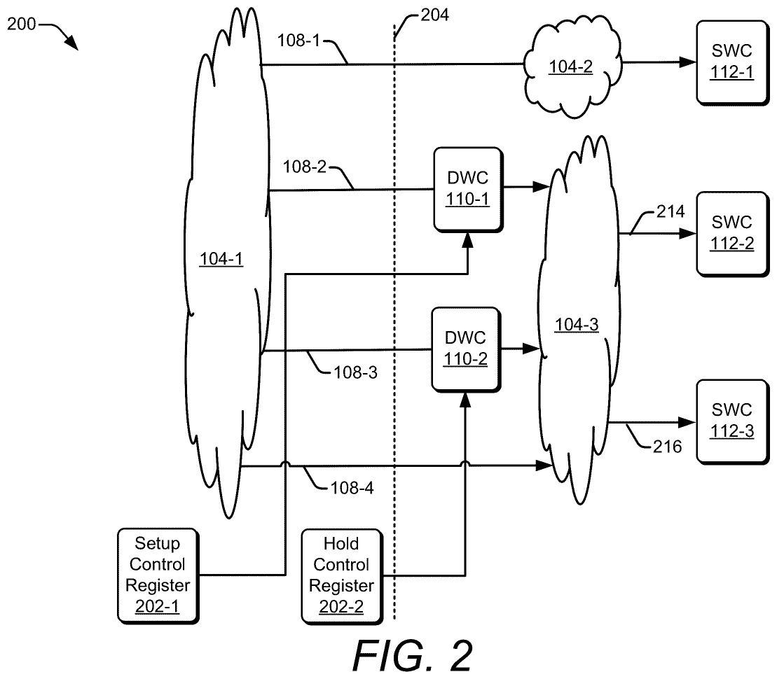

Without the insertion of a value override circuit (e.g., a third dedicated wrapper cell 110-3), the sixth logic 104-6 provides unknown values to the ninth scan flop 102-9 and the tenth scan flop 102-10 of the capture chain 124. To mitigate these unknown values, the third dedicated wrapper cell 110-3 has been inserted on a path through the seventh pin 108-7. The third dedicated wrapper cell 110-3 may be configured to provide that the sixth logic 104-6 provides known values 120, 122 (e.g., a value of zero, a value of one) to the ninth scan flop 102-9 and the tenth scan flop 102-10 during automatic test pattern generation testing. The third dedicated wrapper cell 110-3 may also be configured to enable a functional exception to pass through paths without modifying the values as discussed herein. In this way, value override circuits (e.g., dedicated wrapper cells 110-1, 110-2, 110-3) may be used to implement aspects of reducing unknown values in automatic test pattern generation testing. FIG. 2 illustrates elements that may be used to control the operation of value override circuits that have been inserted along paths that provide unknown values.

FIG. 2 illustrates a schematic of a portion of an example circuit design 200 that utilizes dedicated wrapper cells (e.g., a first dedicated wrapper cell 110-1, a second dedicated wrapper cell 110-2) as value override circuits that implement aspects of reducing unknown values in automatic test pattern generation testing. Like the example circuit design 100 of FIG. 1, the example circuit design 200 of FIG. 2 includes four pins 108-1, 108-2, 108-3, 108-4 that couple a first logic 104-1 with a second logic 104-2, a third logic 104-3, and standard core wrapper cells (e.g., first shared wrapper cell 112-1, second shared wrapper cell 112-2, third shared wrapper cell 112-3) that have been inserted into the circuit design 200 for automatic test pattern generation testing. Without the insertion of value override circuits (e.g., a first dedicated wrapper cell 110-1, a second dedicated wrapper cell 110-2), the third logic 104-3 would provide unknown values to the second shared wrapper cell 112-2 and the third shared wrapper cell 112-3. As discussed herein, the insertion of value override circuits (e.g., the first dedicated wrapper cell 110-1, the second dedicated wrapper cell 110-2) enables the third logic 104-3 to provide known values 214, 216 (e.g., a value of zero, a value of one) to the second shared wrapper cell 112-2 and the third shared wrapper cell 112-3, respectively, during automatic test pattern generation testing. As discussed herein, the first dedicated wrapper cell 110-1 and the second dedicated wrapper cell 110-2 may also be configured to enable a functional exception to pass through the paths without modifying the values.

The circuit design 200 includes a boundary (indicated by dashed line 204), and input for control modes may be added at the boundary 204. The control modes may be used to control a specified dedicated wrapper cell (e.g., dedicated wrapper cells 110-1, 110-2, 110-3). For example, a setup control register 202-1 and a hold control register 202-2 may be added and coupled with the value override circuits (e.g., the first dedicated wrapper cell 110-1, the second dedicated wrapper cell 110-2). The setup control register 202-1 and the hold control register 202-2 may be used to control the operation of the value override circuits (e.g., the first dedicated wrapper cell 110-1, the second dedicated wrapper cell 110-2) to enable the third logic 104-3 to generate known values (e.g., a value of 0, a value of 1) instead of unknown values.

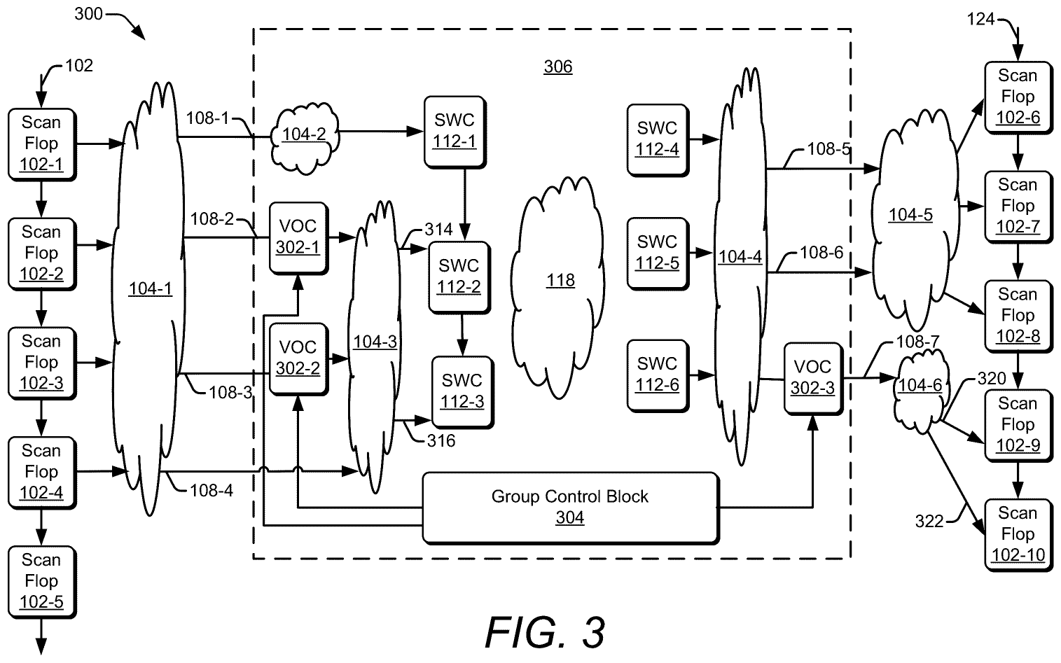

The setup control register 202-1 and the hold control register 202-2 are configured to provide no input, an input of one, or an input of zero to each of the dedicated wrapper cells (e.g., first dedicated wrapper cell 110-1, second dedicated wrapper cell 110-2, third dedicated wrapper cell 110-3) to control the operation of the dedicated wrapper cells. The inputs select a mode of allowing a function exception to pass through the dedicated wrapper cells without modification to any value, modifying an unknown value to the value of zero, or modifying an unknown value to the value of one. As discussed above, the number and/or configuration of the logic (e.g., first logic 104-1, second logic 104-2, third logic 104-3), the control registers (e.g., setup control register 202-1, hold control register 202-2), the pins (e.g., first pin 108-1, second pin 108-2, third pin 108-3, fourth pin 108-4), the value override circuits (e.g., first dedicated wrapper cell 110-1, second dedicated wrapper cell 110-2), and the standard core wrapper cells (e.g., first shared wrapper cell 112-1, second shared wrapper cell 112-2, third shared wrapper cell 112-3) are as shown for illustrative purposes and may be varied within the scope of the disclosure as would be appreciated by one of ordinary skill in the art having the benefit of this disclosure. FIG. 3 shows another example portion of a circuit design that utilizes value override circuits to implement aspects of reducing unknown values in automatic test pattern generation testing.

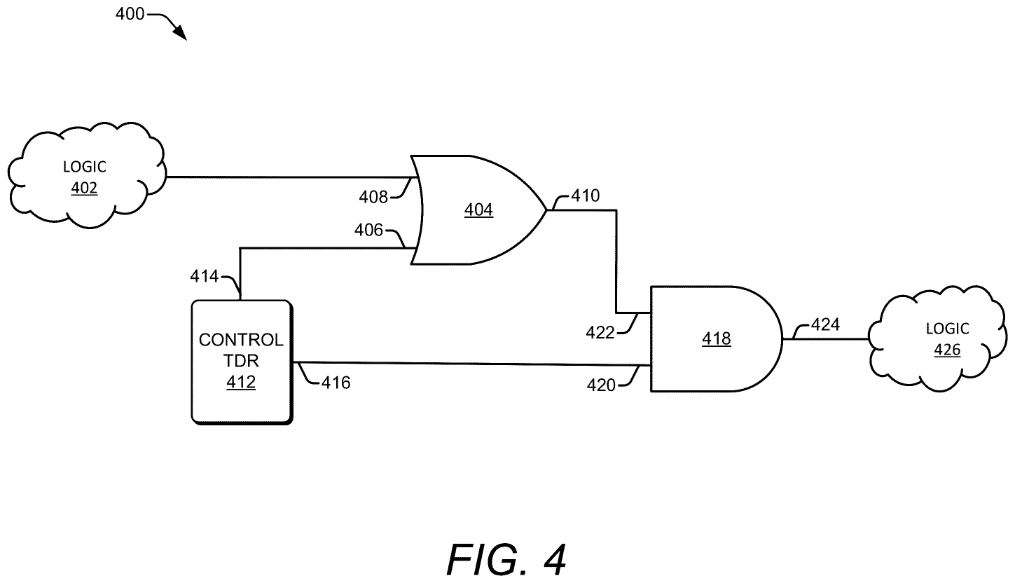

FIG. 3 illustrates a schematic of a portion 306 of an example circuit design 300 that utilizes value override circuits (e.g., VOC 302-1, VOC 302-2, VOC 303-3) that implement aspects of reducing unknown values in automatic test pattern generation testing. The value override circuits 302-1, 302-2, 302-3 may be any circuit configured to reduce unknown values generated during automatic test pattern generation testing by replacing an unknown value with a known value (e.g., a value of zero, a value of one). For example, the value override circuits 302-1, 302-2, 302-3 may be a circuit 400 shown in FIG. 4.

The example circuit design 300 includes a scan chain 102, a capture chain 124, pins (e.g., pins 108-1-108-7), and logic (e.g., logic 104-1-104-6, core logic 118) as discussed in regard to FIG. 1. Paths through the portion 306 of the circuit design 300 that are generating unknown values during automatic test pattern generation testing are determined, and value override circuits (e.g., VOC 302-1, VOC 302-2, VOC 303-3) are inserted into such paths. The value override circuits (e.g., VOC 302-1, VOC 302-2, VOC 303-3) are configured to change the unknown values to either a value of zero or a value of one depending on the mode configuration. Likewise, the value override circuits (e.g., VOC 302-1, VOC 302-2, VOC 303-3) may be configured to allow a functional exception to pass along a path without modifying any values.

As discussed before, the third logic 104-3 provides unknown values to a second shared wrapper cell 112-2 and a third shared wrapper cell 112-3 without the insertion of value override circuits (e.g., VOC 302-1, VOC 302-2). Likewise, the sixth logic 104-6 provides unknown values to the ninth scan flop 102-9 and the tenth scan flop 102-10 of the capture chain 124 without the insertion of a value override circuit (e.g., VOC 302-3) along the path. With the insertion of value override circuits (e.g., VOC 302-1, VOC 302-2) along scan paths, the third logic 104-3 provides known values 314, 316 (e.g., a value of zero, a value of one) to the second shared wrapper cell 112-2 and the third shared wrapper cell 112-3. With the insertion of a value override circuit (e.g., VOC 303-3) along a scan path, the sixth logic 104-6 provides known values 320, 322 (e.g., a value of zero, a value of one) to the ninth scan flop 102-9 and the tenth scan flop 102-10, respectively.

A group control block 304 is added to the portion 306 of the circuit design 300. The group control block 304 may be coupled to each of the value override circuits (e.g., VOC 302-1, VOC 302-2) and is configured to individually control the value override circuits. The group control block 304 may be coupled to more, or fewer, than three value override circuits (e.g., VOC 302-1, VOC 302-2) as shown in FIG. 3 as would be appreciated by one of ordinary skill in the art having the benefit of this disclosure. The value override circuit (e.g., VOC 302-1, VOC 302-2) may include the elements shown in an example value override circuit of FIG. 4.

FIG. 4 illustrates a schematic of an example value override circuit 400 that implements aspects of reducing unknown values in automatic test pattern generation testing. The value override circuit 400 includes an OR gate 404 coupled with an AND gate 418 and a control transmit data register 412 (CONTROL TDR 412) coupled with the OR gate 404 and the AND gate 418. The control transmit data register 412 is configured to provide a first input value 414 (e.g., a value of zero, a value of one, or an unknown value) to a first input 406 of the OR gate 404 and to provide a second input value 416 (e.g., a value of zero, a value of one, or an unknown value) to a first input 420 of the AND gate 418. A second input 408 of the OR gate 404 is coupled with logic 402 of a circuit design. Likewise, an output 424 of the AND gate 418 is coupled with logic 426 of the circuit design. An output 410 of the OR gate 404 is coupled to a second input 422 of the AND gate 418. The control transmit data register 412 may be used to control the mode operation of the value override circuit 400 as the control transmit data register 412 is coupled to the first input 406 of the OR gate 404 and the first input 420 of the AND gate 418.

In one aspect, a group control block 304 (shown in FIG. 3) may be configured to individually control the control transmit data register 412 of each value override circuit 400 coupled to the group control block 304. For example, the group control block 304 may cause the first input value 414 from the control transmit data register 412 to be the value of zero and the second input value 416 from the control transmit data register 412 to be the value of one, which places the value override circuit 400 into a “transparent” mode that enables a functional exception to pass through the value override circuit 400 with no medication of the value. In another mode, the group control block 304 may cause the first input value 414 from the control transmit data register 412 to be the value of one and the second input value 416 from the control transmit data register 412 to be the value of one, which causes the value override circuit 400 to output a value of one at the output 424 of the AND gate 418. Similarly, in another mode, the group control block 304 may cause the first input value 414 from the control transmit data register 412 to be an unknown value and the second input value 416 from the control transmit data register 412 to be the value of zero, which causes the value override circuit 400 to output a value of zero at the output 424 of the AND gate 418. In these ways, the total number of unknown values for a circuit design may be reduced in automatic test pattern generation testing.

### Example Methods

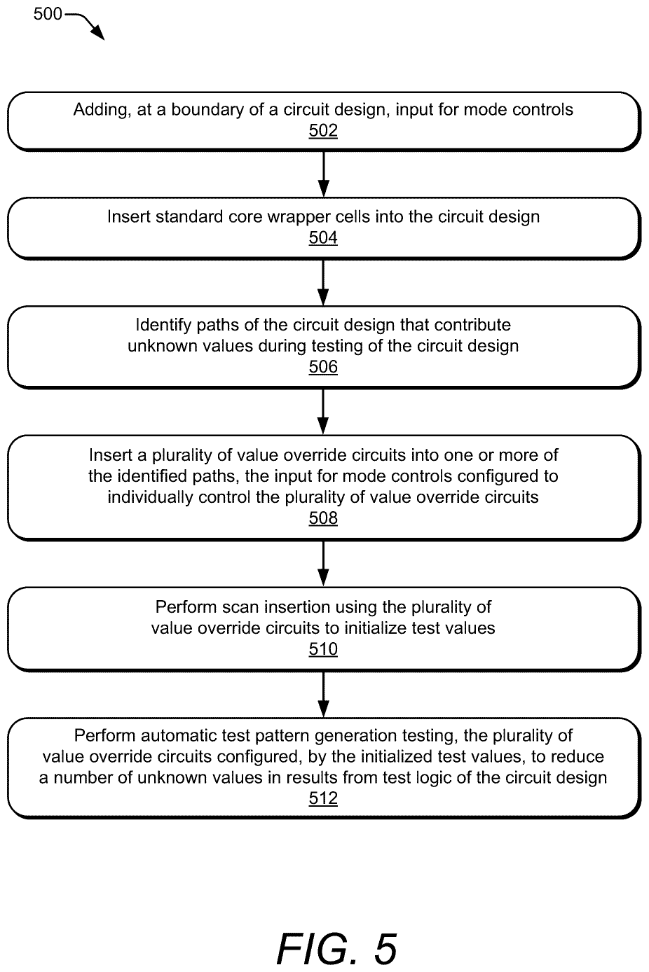

FIG. 5 is a flowchart that illustrates a method 500 for reducing unknown values in automatic test pattern generation testing, which includes operations 502 through 512. At step 502, input for mode controls is added at a boundary of a circuit design. For example, mode controls (e.g., setup control register 202-1, hold control register 202-2) may be added at a boundary 204 of a circuit design 200.

At step 504, standard core wrapper cells are inserted into the circuit design. For example, standard core wrapper cells (e.g., shared wrapper cells 112-1-112-6) are inserted into the circuit design (e.g., a portion 106 of the circuit design 100).

At step 506, paths of the circuit design that contribute unknown values (e.g., sources of X) during testing of the circuit design are identified. For example, paths (e.g., pins 108-1-108-7) are identified of the circuit design 100 that contribute unknown values during testing (e.g., automatic test pattern generation testing).

At step 508, a plurality of value override circuits are inserted into one or more of the identified paths, the input for mode controls configured to individually control the plurality of value override circuits. For example, a plurality of value override circuits (e.g., dedicated wrapper cells 110-1-110-3, value override circuits VOC 302-1-302-3) are inserted into one or more of the identified paths. Input for mode controls (e.g., setup control register 202-1, hold control register 202-2, group control block 304) is configured to individually control the plurality of value override circuits (e.g., dedicated wrapper cells 110-1-110-3, value override circuits VOC 302-1-302-3). The plurality of value override circuits may be dedicated wrapper cells. For example, the plurality of value override circuits may be dedicated wrapper cells (e.g., DWC 110-1-110-3). The plurality of value override circuits may include an OR gate coupled with an AND gate and a control transmit data register. For example, the value override circuits may include an OR gate (e.g., OR gate 404) coupled with an AND gate (e.g., AND gate 418) and a control transmit data register (e.g., control transmit data register 412).

At step 510, scan insertion is performed using the plurality of value override circuits to initialize test values. For example, scan insertion is performed using the plurality of value override circuits (e.g., dedicated wrapper cells 110-1-110-3, value override circuits VOC 302-1-302-3) to initialize test values.

At step 512, automatic test pattern generation testing is performed, the plurality of value override circuits configured, by the initialized test values, to reduce a number of unknown values in results from test logic of the circuit design. For example, automatic test pattern generation testing is performed with the plurality of value override circuits (e.g., dedicated wrapper cells 110-1-110-3, value override circuits VOC 302-1-302-3) configured, by the initialized test values, to reduce a number of unknown values in results from test logic of the circuit design (e.g., automatic test pattern generation testing).

For the methods described herein and the associated flow chart(s) and flow diagram(s), the orders in which operations are shown and/or described are not intended to be construed as a limitation. Instead, any number or combination of the described method operations can be combined in any order to implement a given method or an alternative method, including by combining operations from the flow chart or diagram and the earlier-described schemes and techniques into one or more methods. Operations may also be omitted from or added to the described methods. Further, described operations can be implemented in fully or partially overlapping manners.

### CONCLUSION

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Terms such as “above,” “below,” or “underneath” are not intended to require any particular orientation of a device. Rather, a first layer or component being provided “above” a second layer or component is intended to describe the first layer being at a higher Z-dimension than the second layer or component within the particular coordinate system in use. It will be understood that should the component be provided in another orientation, or described in a different coordinate system, then such relative terms may be changed.

Although implementations for reducing unknown values in automatic test pattern generation testing have been described in language specific to certain features and/or methods, the subject of the appended claims is not necessarily limited to the specific features or methods described. Rather, the specific features and methods are disclosed as example implementations for reducing unknown values in automatic test pattern generation testing.

What is claimed is:

1. A method for reducing unknown values in automatic test pattern generation comprising:
adding, at a boundary of a circuit design, input for mode controls;
inserting standard core wrapper cells into the circuit design;
identifying paths of the circuit design that contribute to unknown values during testing of the circuit design;
inserting a plurality of value override circuits into one or more of the identified paths, the input for mode controls configured to individually control the plurality of value override circuits;
performing scan insertion using the plurality of value override circuits to initialize test values; and
performing automatic test pattern generation testing, the plurality of value override circuits configured, by the initialized test values, to reduce a number of unknown values in results from test logic of the circuit design.

2. The method of claim 1, wherein the plurality of value override circuits comprise dedicated wrapper cells.

3. The method of claim 2, wherein the mode controls include a setup control register and a hold control register for the dedicated wrapper cells.

4. The method of claim 3, wherein the setup control register and the hold control register are configured to:
enable a function exception to pass through a specified one of the dedicated wrapper cells located on one of the identified paths;
enable the specified one of the dedicated wrapper cells to provide a value of zero; or
enable the specified one of the dedicated wrapper cells to provide a value of one.

5. The method of claim 1, wherein the plurality of value override circuits each include an OR gate coupled with an AND gate and a control transmit data register coupled with the OR gate and the AND gate, the control transmit data register configured to provide a value of zero, a value of one, or an unknown value to a first input of the OR gate and to provide a value of zero or a value of one to a first input of the AND gate.

6. The method of claim 5, further comprising:
adding a group control block coupled with the plurality of value override circuits, the group control block configured to individually control the control transmit data register of each value override circuit of the plurality of value override circuits coupled with the group control block.

7. The method of claim 6, wherein a second input of the OR gate is coupled with logic of the circuit design and an output of the OR gate is coupled with a second input of the AND gate.

8. The method of claim 7, wherein an output of the AND gate is coupled with logic of the circuit design.

9. The method of claim 8, further comprising:
providing, with the control transmit data register of a first value override circuit of the plurality of value override circuits, a value of zero to the first input of the OR gate, of the first value override circuit, and a value of one to the first input of the AND gate, of the first value override circuit, enables a functional exception to pass through the first value override circuit;
providing, with the control transmit data register of the first value override circuit, a value of one to the first input of the OR gate, of the first value override circuit, and a value of one to the first input of the AND gate, of the first value override circuit, provides the output of the AND gate to be a value of one; and
providing, with the control transmit data register of the first value override circuit, an unknown value to the first input of the OR gate, of the first value override circuit, and a value of zero to the first input of the AND gate, of the first value override circuit, provides the output of the AND gate to be a value of zero.
